(19) United States
(12) Patent Application Publication
(10) Pub. No.: US 2005/0127374 A1
(43) Pub. Date: Jun. 16, 2005

(54) Light-emitting device and forming method thereof

(76) Inventors: Chao-Huang Lin, Taoyuan Hsien (TW); Bor-Jen Wu, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/735,701

(22) Filed: Dec. 16, 2003

(51) Int. Cl. H01L 29/26

(52) U.S. Cl. 257/79

(57) ABSTRACT

A light-emitting device and forming method thereof are disclosed. The light-emitting device has a rhombus shape and electrode pads on the longer diagonal of the rhombus shape so that the distance between the electrode pads are larger without decreasing the light-emitting area. Furthermore, since the rhombus shape of the LED is formed aligned with the easy crack direction of the substrate, the yield ratio of production is higher. The light-emitting device can be packaged by a flip chip package process.

### BACKGROUND OF THE INVENTION

1. Field of the Invention

The present invention relates to a light-emitting device and a forming method thereof, and more particularly to a light-emitting device with a high yield ratio and a larger light-emitting area, and a forming method thereof.

2. Description of the Related Art

In recent years, attention has been paid to gallium nitride-based compound semiconductors, such as GaN, as materials of short-wavelength light emitting diodes (LED) for use in a range between green light, blue light and ultraviolet. The short-wavelength light emitting diodes can be applied to full color applications of green and blue light and generation of white light via energy transformation, because of its short oscillation wavelength or high frequency.

Conventionally, it has been proposed to arrange a pair of electrodes on diagonally opposite sides in order to increase the light-emitting area of a gallium nitride-based/sapphire compound light emitting diode. However, in order to power the light emitting diode, bonding wires are formed to connect the electrodes such as metal pads or contact pads on the top surface of the light emitting diode with a drive circuit. Unfortunately, the bonding wires would shade and reduce the light-emitting area. Moreover, the structure of conventional light emitting diodes would cause electrical current concentrating between two metal pads so as to reduce the operation life of the light emitting diodes.

As described above, a light-emitting device of compound semiconductors arranged on an insulating substrate needs to have a pair of electrodes arranged on its light-output face. Since the electrodes need to be connected to bonding wires, and thus should not be so small, the electrodes cause a decrease in the light-emitting area. Furthermore, since the electrodes of a LED having a square shape are on the two ends of one diagonal, the electrodes would be too close and the electrical circuit would concentrate between the electrodes as the size of the LED further shrinks so as to degrade the performance and the reliability of the light-emitting diode. Furthermore, the yield ratio of wire bonding would also be decreased since the electrodes are so close. Moreover, due to the hexagonal lattice of the sapphire substrate, scribing the sapphire substrate to LEDs with a square shape would induce cracks and degrade the yield ratio.

In view of the drawbacks mentioned with the prior art device and process thereof, there is a continued need to develop new and improved device structures and processes that overcome the disadvantages associated with prior art device structures and processes. The advantages of this invention are that it solves the problems mentioned above.

### SUMMARY OF THE INVENTION

It is therefore an object of the invention to upgrade the scribing yield ratio of LED.

It is therefore an object of the invention to provide a flip chip LED with a smaller size.

It is therefore an object of the invention to provide a LED with an enough electrode pad distance even if the size of the LED shrinks.

It is another object of this invention to provide a LED with uniform brightness.

It is another object of this invention to provide a method for forming LED which can increase yield ratio and throughput.

It is therefore an object of the invention to provide a LED with a large light emitting area.

To achieve these objects, and in accordance with the purpose of the invention, the invention provides a method for forming a semiconductor light-emitting device, said method comprises the following steps. First of all, a substrate is provided. Then a first doped semiconductor layer with a first conductivity type is formed on said substrate. Next an active light-emitting layer is formed on said first doped semiconductor layer. Then a second doped semiconductor layer with a second conductivity type is formed on said active light-emitting layer. Next a transparent conductive layer is formed on said second doped semiconductor layer. Then a plurality of first electrode patterns of a plurality of first rhombus patterns are transferred into said transparent conductive layer, said second doped semiconductor layer, said active light-emitting layer and a predetermined depth of said first doped semiconductor layer, wherein each said first electrode pattern is on one end of the longer diagonal of each said first rhombus pattern, and at least one side of said first rhombus pattern is parallel to a easy crack direction of said substrate. Next a dielectric layer is formed over said substrate. Then a plurality of said first and second electrode patterns of a plurality of second rhombus patterns are transferred into said dielectric layer to expose a portion of said transparent conductive layer and said first doped semiconductor layer, wherein each said first and said second electrode patterns are respectively on two ends of the longer diagonal of each said second rhombus pattern, and at least one side of said second rhombus pattern is parallel to a easy crack direction of said substrate. Next a plurality of first electrodes and second electrodes are formed on said exposed first doped semiconductor layer and said exposed transparent conductive layer. Then said substrate is divided to form a plurality of devices having a rhombus shape.

It is to be understood that both the foregoing general description and the following detailed description are exemplary and explanatory only and are not restrictive of the invention, as claimed.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A shows a light-emitting device according to an embodiment of the present invention;

FIG. 1B shows a wafer having a plurality of light-emitting devices as shown in FIG. 1A;

FIG. 1C shows a top view of a light-emitting device according to one embodiment of the invention;

FIG. 1D shows a top view of a light-emitting device according to another embodiment of the invention;

FIG. 1E shows a top view of a light-emitting device according to another embodiment of the invention;

FIG. 1F shows a light-emitting device according to another embodiment of the invention mounting on electrodes by a flip chip package method; and

FIG. 1G shows a light-emitting device according to another embodiment of the invention mounting on a circuit board by a flip chip package method.

### DESCRIPTION OF THE PREFERRED EMBODIMENT

It is to be understood and appreciated that the process steps and structures described below do not cover a complete process flow and structures. The present invention can be practiced in conjunction with various fabrication techniques that are used in the art, and only so much of the commonly practiced process steps are included herein as are necessary to provide an understanding of the present invention.

The present invention will be described in detail with reference to the accompanying drawings. It should be noted that the drawings are in greatly simplified form and they are not drawn to scale. Moreover, dimensions have been exaggerated in order to provide a clear illustration and understanding of the present invention.

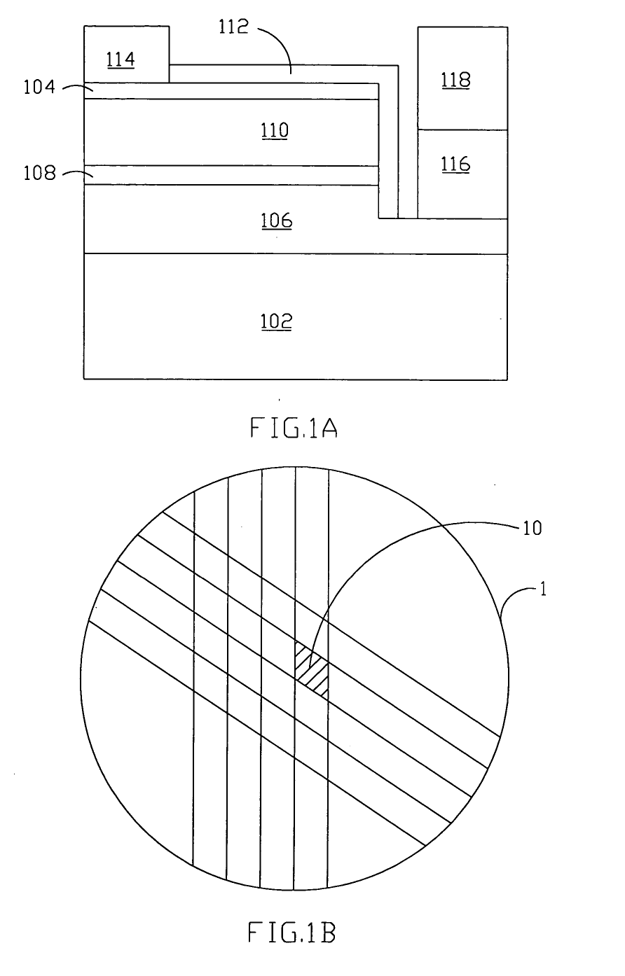

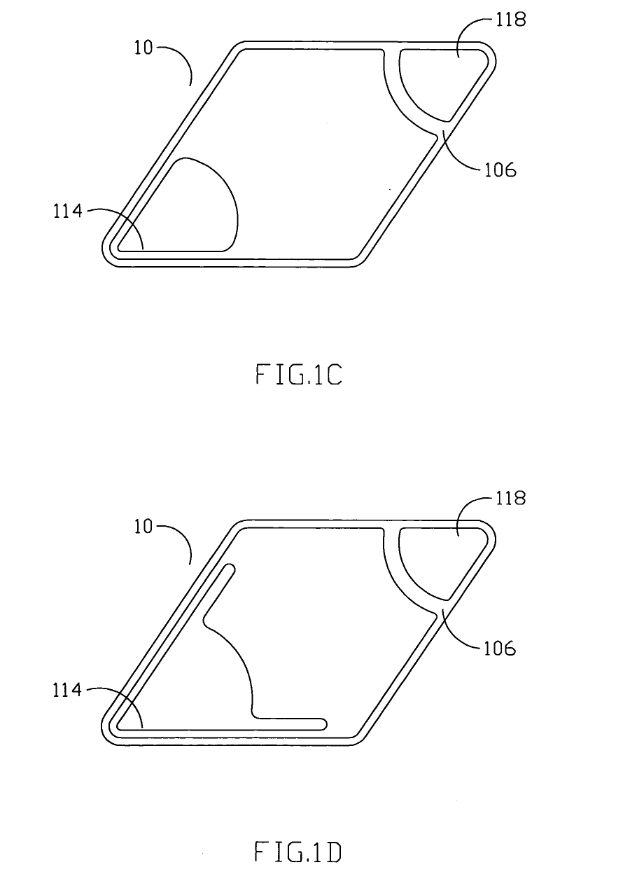

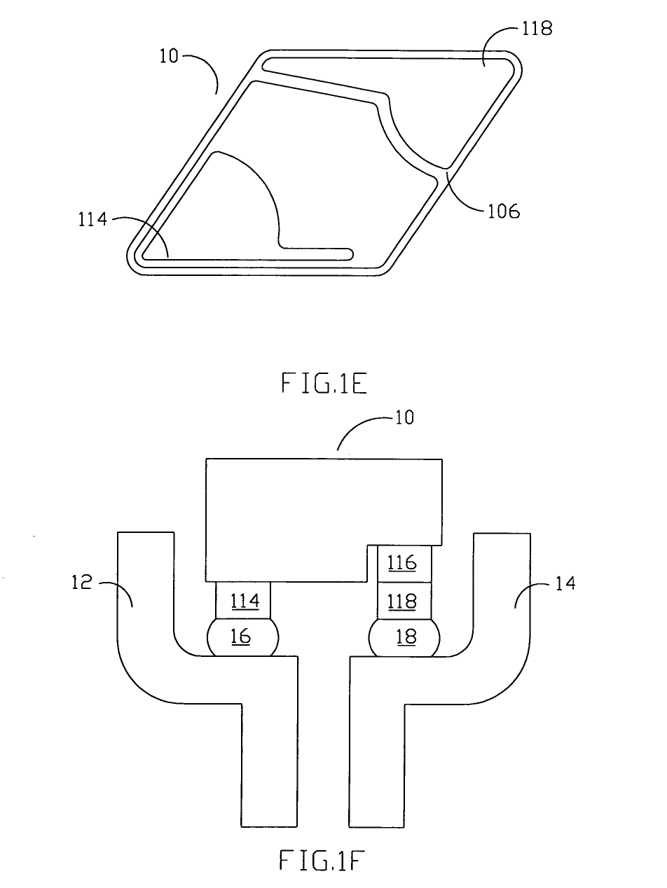

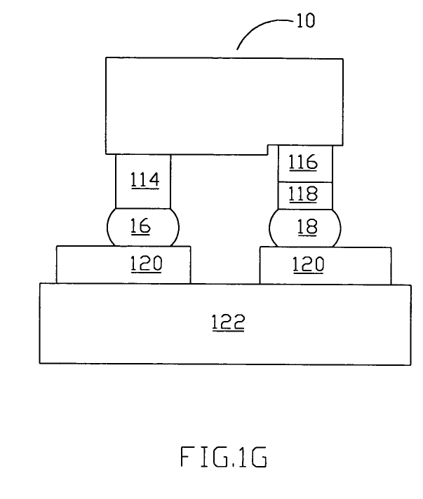

Referring to FIG. 1A, a light-emitting device 10 according to an embodiment of the present invention is shown. The light-emitting diode device includes a substrate 102, on which a multi-layer structure such as a multi-layer structure of GaN-based materials is arranged. The multi-layer structure can be formed by a MOCVD (Metal Organic Chemical Vapor Deposition) method. Moreover, a molecular beam epitaxy (MBE) method or a CVD method may be used, in place of the MOCVD method. The multi-layer structure also includes semiconductor layers 106, 108 and 110.

The multi-layer structure also includes a transparent conductive (TCL) layer 104 and the semiconductor layer 108 includes an active (light-emitting) layer. The semiconductor layers 106 and 110 comprises compound semiconductor layers with opposite conductivity types (n-type or p-type). The semiconductor layers 106 and 110 can further include a multi-semiconductor layer structure. This multi-semiconductor layer structure comprises undoped semiconductor layer as buffer layers or cladding layer or AlGaN/GaN and InGaN layers. The semiconductor layers comprise III-V group semiconductor layers.

The light-emitting diode devices each having a rhombus shape can be formed by a variety of processes. In one embodiment, the semiconductor layers 106, 108 and 110 can be formed on the substrate 102 by an epitaxy method. Then portions of the semiconductor layers 110, 108 and 106 are etched to form a trench for accommodating one electrode which connects the semiconductor layer 106. Next the transparent conductive layer 104 and a transparent dielectric layer 112 are formed. Then electrodes are formed on the two ends of the longer diagonal of the rhombus shape. Finally, the light-emitting diode devices are separated along the scribing lines shown in FIG. 1B. The light-emitting diode device having a rhombus shape of the invention can also be formed by other processes. The electrode 114, 116 and 118 are example only. The electrodes 114 and 116 can be formed simultaneously with the same material or be formed with different materials. The electrode 118 can also be omitted. The rhombus shape pattern and the electrodes can be formed by using photolithography and etching processes. The electrodes 114, 116 and 118 and the transparent conductive layer 104 can be formed by photolithography, physical and chemical deposition or evaporation processes. The dielectric layer isolates the semiconductor layers 106 and 110. The semiconductor layers 106 and 110 connect to a drive circuit through the electrodes 116 and 114 respectively. The dielectric layer 112 can be a silicon dioxide layer or a silicon nitride layer or other transparent polymer layer. The dielectric layer 112 can be formed by photolithography, physical and chemical deposition processes. The dielectric layer 112 is formed for flip chip device and can be omitted for non-flip chip device.

If GaN-based compound semiconductors are utilized, the substrate 102 comprises a sapphire substrate with a hexagonal lattice. A sapphire substrate is apt to crack easily in <11-20> directions, but relatively little in <1-100> directions perpendicular thereto. The semiconductor layers 106 and 110 comprise a first doped GaN layer with a first conductivity type and a second doped GaN layer with a second conductivity type. The semiconductor layers 106 and 110 can also comprise undoped buffer/cladding GaN layers. For example, the semiconductor layers 106 and 110 can be an N type layer and a P type layer, and the electrodes 114 and 116 can be a P type electrode and an N type electrode. Moreover, the substrate 102 can also be a SiC substrate or other high-temperature resistant transparent substrate.

Referring to FIG. 1B, a wafer 1 having a plurality of light-emitting devices 10 as shown in FIG. 1A is shown. The light-emitting device 10 has a rhombus shape or contour and the electrodes 114 and 118 on the two ends longer diagonal as shown in FIG. 1C. FIG. 1D and FIG. 1E show other embodiments of the electrodes 114 and 118 respectively. The electrode 114 in FIG. 1D includes two extended areas to keep the distance variations between any two points respectively on the electrodes 114 and 118 limited. The electrodes 114 and 118 in FIG. 1E include two extended areas respectively to keep the distance between any two points respectively on the electrodes 114 and 118 uniform. Grooves or trenches can be formed on the slicing lines separating adjacent light-emitting devices shown in FIG. 1C in order to scribe conveniently. The slicing lines are about parallel to a easy-crack direction of the substrate.

Referring to FIG. 1F, the light-emitting diode device 10 of the invention is mounted on electrodes 12 and 14 through conductive bumps 16 and 18. The electrodes 12 and 14 connect a circuit to form a light-emitting diode lamp. The light-emitting diode device 10 connects the conductive bumps 16 and 18 through the electrodes 114 and 118 by a flip chip package process. The light-emitting diode device 10 can also be packages by a surface mounting technology. The electrode 118 can also be omitted. The conductive bumps 16 and 18 can also be replaced with a adhesive conductive film.

Referring to FIG. 1G, the light-emitting diode device 10 is mounted a circuit board 122 through contact pads 120 of by a flip chip package process. The contact pads 120 connect to a circuit of the circuit board 122. The light-emitting diode device 10 connects the circuit board 122 through the soldering or adhesive conductive film between the contact pads 120 the electrodes 114 and 118 by a flip chip package process. The contact pads 120 can also connect the electrodes 114 and 118 via the conductive bumps 16 and 18. The light-emitting diode device 10 can also be packages by a surface mounting technology.

The invention utilizes the characteristics of the crystal lattice of the sapphire substrate to slice a wafer along the easy crack direction of the sapphire substrate and form light-emitting devices having a rhombus shape. Therefore, a light-emitting device having a larger light-emitting area, a longer electrode distance is provided, and the yield ratio and throughput of production, especially the scribing yield ratio, can also be upgraded. Moreover, the concentration of electrical current between electrodes as the size of the device decreases can also be avoided. Furthermore, since a flip chip package is used and the electrodes are formed on the longer diagonal of the rhombus light-emitting device, the size of the device can be further reduced and the brightness can be more uniform.

Other embodiments of the invention will appear to those skilled in the art from consideration of the specification and practice of the invention disclosed herein. It is intended that the specification and examples to be considered as exemplary only, with a true scope and spirit of the invention being indicated by the following claims.

1. A light-emitting diode device, said light-emitting diode device comprising:
a substrate;
a multi-layer compound semiconductor structure having a rhombus shape on said substrate, wherein one pair of parallel sides of said rhombus shape are parallel to a easy crack direction of said substrate; and
a first electrode and a second electrode on two ends of the longer diagonal of said rhombus shape respectively.

2. The light-emitting diode device according to claim 1, wherein said substrate comprises a sapphire substrate.

3. The light-emitting diode device according to claim 1, wherein said multi-layer compound semiconductor structure comprises:
a first doped semiconductor layer with a first conductivity type on said substrate;
an active light-emitting layer on said first doped semiconductor layer;
a second doped semiconductor layer with a second conductivity type on said active light-emitting layer;
a transparent conductive layer on said second doped semiconductor layer;
trench on one end of the longer diagonal of said rhombus shape, said trench has a predetermined depth in said first doped semiconductor layer to accommodate said second electrode to connect said first doped semiconductor layer, and expose a portion of said second doped semiconductor layer, a portion of said active light-emitting layer and a portion of said first doped semiconductor layer; and
a dielectric layer covering said transparent conductive layer, said exposed portion of said second doped semiconductor layer, said exposed portion of said active light-emitting layer and said exposed portion of said first doped semiconductor layer to isolate said first electrode and said second electrode.

4. The light-emitting diode device according to claim 3, wherein said first doped semiconductor layer and said second doped semiconductor layer comprise III-V group semiconductor layers.

5. The light-emitting diode device according to claim 3, wherein said first doped semiconductor layer and said second doped semiconductor layer comprise doped GaN semiconductor layers.

6. The light-emitting diode device according to claim 3, wherein said dielectric layer comprises a silicon dioxide layer.

7. The light-emitting diode device according to claim 3, wherein said dielectric layer comprises a silicon nitride layer.

8. The light-emitting diode device according to claim 3, wherein said dielectric layer comprises a transparent polymer layer.

9. The light-emitting diode device according to claim 3, wherein said first doped semiconductor layer and said second doped semiconductor layer comprise a N type doped semiconductor layer and a P type doped semiconductor layer.

10. The light-emitting diode device according to claim 1 further comprises two bumps formed on said first electrode and said second electrode respectively for flip chip package processes.

11. The light-emitting diode device according to claim 1 further comprises two bumps formed on said first electrode and said second electrode respectively for surface mounting technologies.

12. The light-emitting diode device according to claim 1 further comprises adhesive conductive films on said first electrode and said second electrode respectively for flip chip package processes.

13. The light-emitting diode device according to claim 1 further comprises adhesive conductive films on said first electrode and said second electrode respectively for surface mounting technologies.

14-27. (canceled)
